(19) United States
(12) Patent Application Publication
(10) Pub. No.: US 2022/0075269 A1
(43) Pub. Date: Mar. 10, 2022

(54) DOUBLE EXPOSURE PROCESS

(71) Applicant: UNITED MICROELECTRONICS CORP., Hsin-Chu City (TW)

(72) Inventor: Ting Huo, Singapore (SG)

(21) Appl. No.: 17/013,880

(22) Filed: Sep. 8, 2020

(51) Int. Cl. G03F 7/20; G03F 1/26

(52) U.S. Cl. CPC G03F 7/2022; G03F 1/26

(57) ABSTRACT

A double exposure process includes providing a reticle including two different patterns arranged alternatedly in columns. A wafer covered by a photoresist is provided. Later, a double exposure process is performed. The double exposure process includes steps of: performing a first exposure by illuminating a light through the reticle to transfer patterns onto the photoresist. Later, the reticle is moved a distance of a width of one column. Finally, a second exposure is performed by illuminating the light through the reticle to transfer the patterns onto the photoresist.

### BACKGROUND OF THE INVENTION

### 1. Field of the Invention

The present invention relates to a double exposure process, and more particularly to a process which only utilizes one reticle to perform a double exposure process.

### 2. Description of the Prior Art

Lithography processing is a required and essential technology when manufacturing conventional integrated circuits. Many lithography techniques exist, and all lithography techniques are used for the purpose of defining geometries, features, lines, or shapes onto an integrated circuit die or wafer.

Because semiconductor manufacturing process advancements are driving the corresponding geometric dimensions of semiconductor devices to decreasingly smaller values, the gap between the required feature size and the resolution that the lithography wavelength can reach gets bigger, the final wafer images are quite different from the patterns on the mask.

A double patterning process has been developed as a cost-effective way to further scale into the deep submicron domain, using the same lithographic technology. One popular form of double patterning is the double exposure lithography, wherein a given layout is split or decomposed into two sets of patterns, each of which is printed using a separate mask in a separate exposure step. The desired layout may be constructed by these two separate patterns.

The greatest advantage of double exposure lithography is that we can use available photo-lithography technology and tools to manufacture finer patterns with even higher density. However, there are still many process issues to overcome in practice.

### SUMMARY OF THE INVENTION

Therefore, it is still necessary to improve the conventional double exposure process in order to achieve finer resolution.

According to a preferred embodiment of the present invention, a double exposure process includes providing a reticle comprising n×m regions that is arranged in n rows and m columns, wherein m is a positive integer starting from 1, 2 to A, A is not less than 2 and n is a positive integer starting from 1 to B, B is not less than 1, each of the regions has the same length and the same width, a first pattern is disposed within an mth column of the n×m regions with an odd-numbered m, and a second pattern is disposed within an mth column of the n×m region with an even-numbered m, and the first pattern is different from the second pattern. A wafer covered by a photoresist is provided. Later, a double exposure process is performed. The double exposure process includes steps of:

Step (a): performing a first exposure by illuminating a light through the n×m regions on the reticle to transfer the second pattern onto the photoresist;

Step (b): moving the reticle a distance of the width along a first direction which is parallel to the rows; and

Step (c): performing a second exposure by illuminating the light through the n×m regions on the reticle to transfer the first pattern and the second pattern onto the photoresist; wherein the steps are performed in a sequence of Step (a), Step (b) to Step (c).

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 3 depict a double exposure process according to a first preferred embodiment of the present invention, wherein:

FIG. 3 is a fabricating stage following FIG. 1.

FIG. 2 shows a first pattern and a second pattern on a photoresist after Step (a).

FIG. 4 shows a first pattern and a second pattern on a photoresist after Step (c).

FIG. 5 to FIG. 8 shows a double exposure process according to a second preferred embodiment of the present invention, wherein:

FIG. 6 is a fabricating stage following FIG. 5;

FIG. 7 is a fabricating stage following FIG. 6; and

FIG. 8 is a fabricating stage following FIG. 7.

FIG. 9 shows another exposure method according to a third preferred embodiment of the present invention.

FIG. 10 to FIG. 11 show an example of a first pattern and an example of a second pattern according to a fourth preferred embodiment of the present invention, wherein:

FIG. 11 is a fabricating stage following FIG. 10.

### DETAILED DESCRIPTION

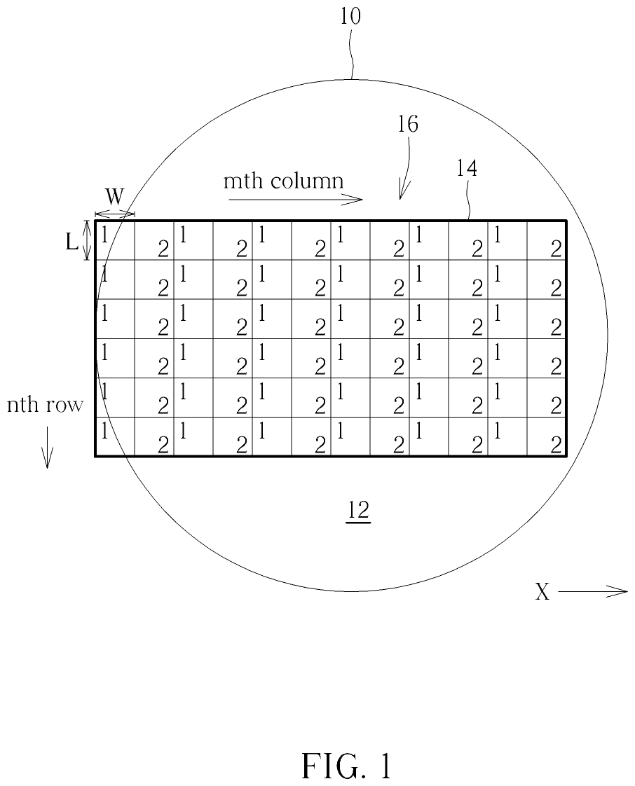

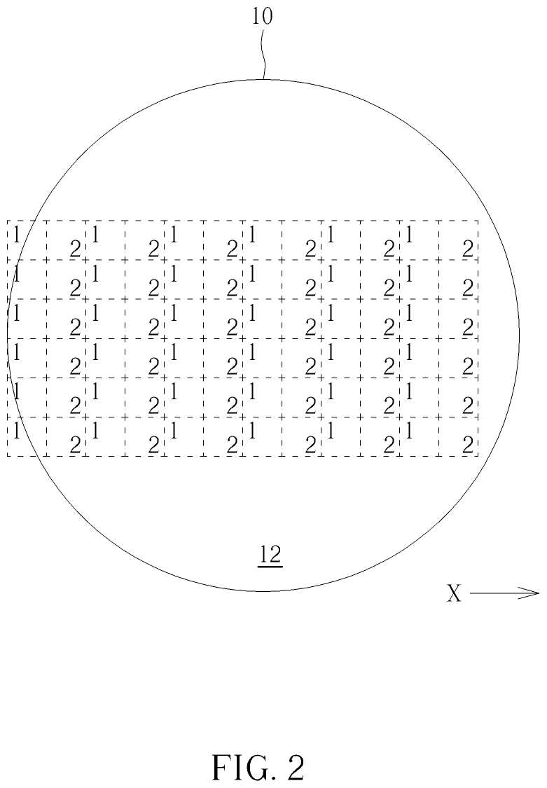

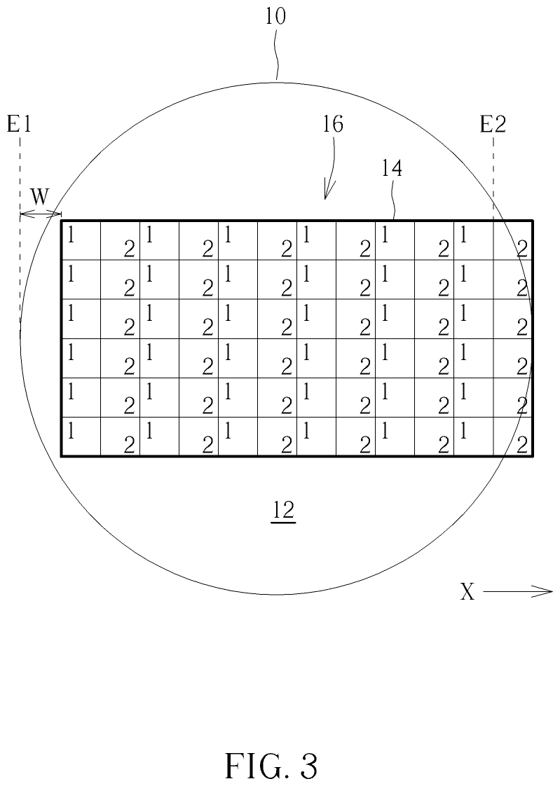

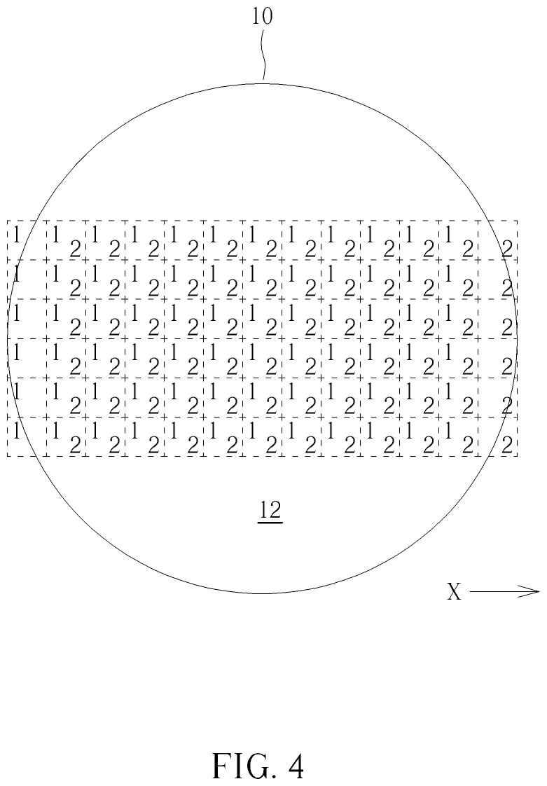

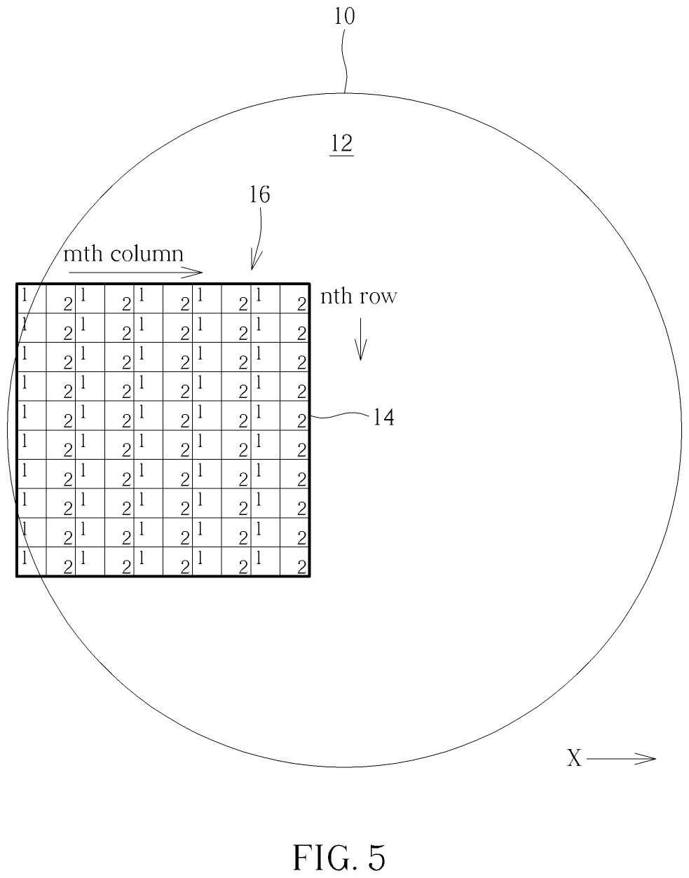

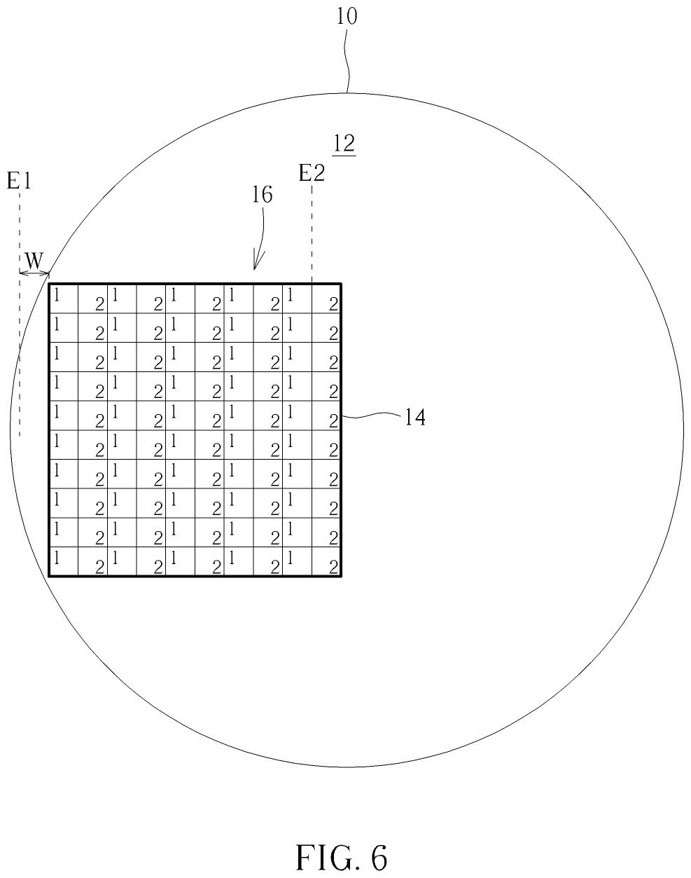

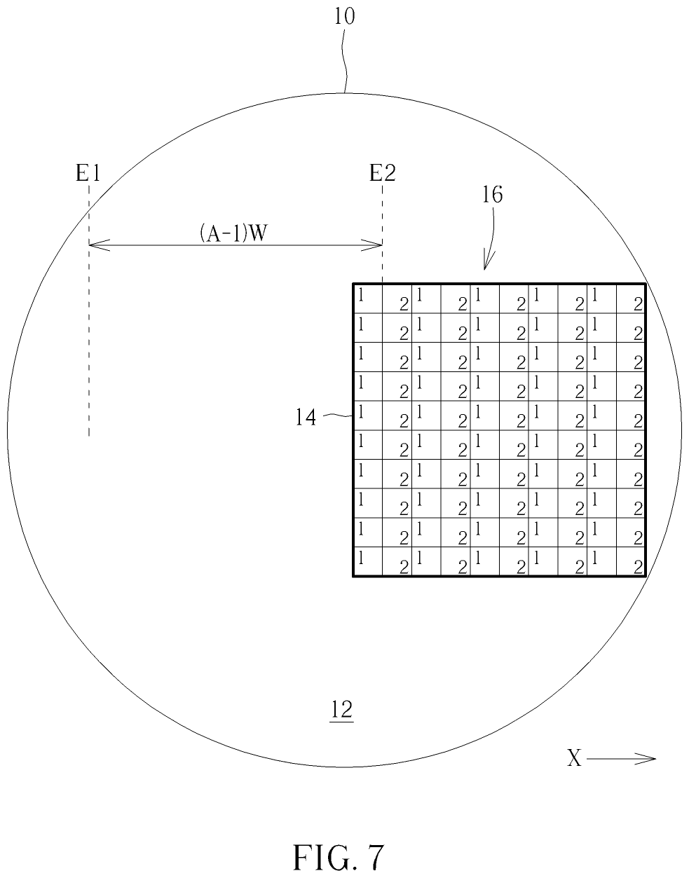

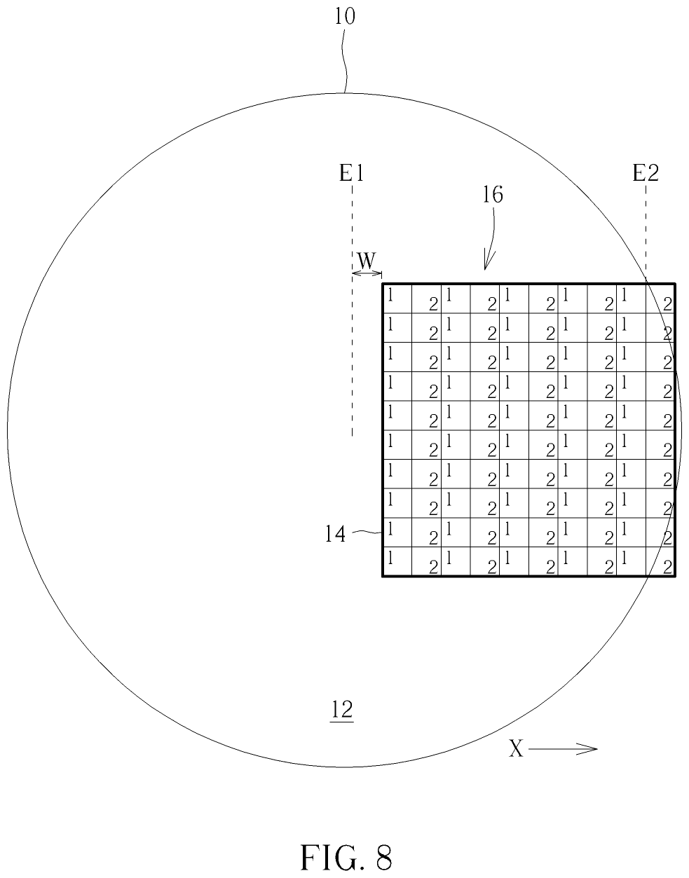

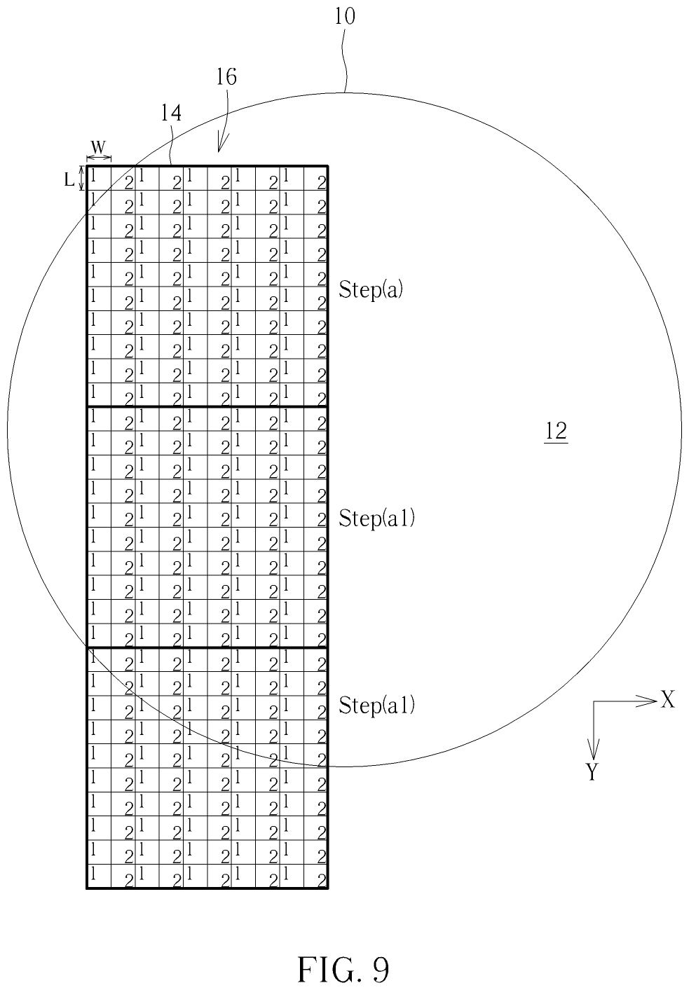

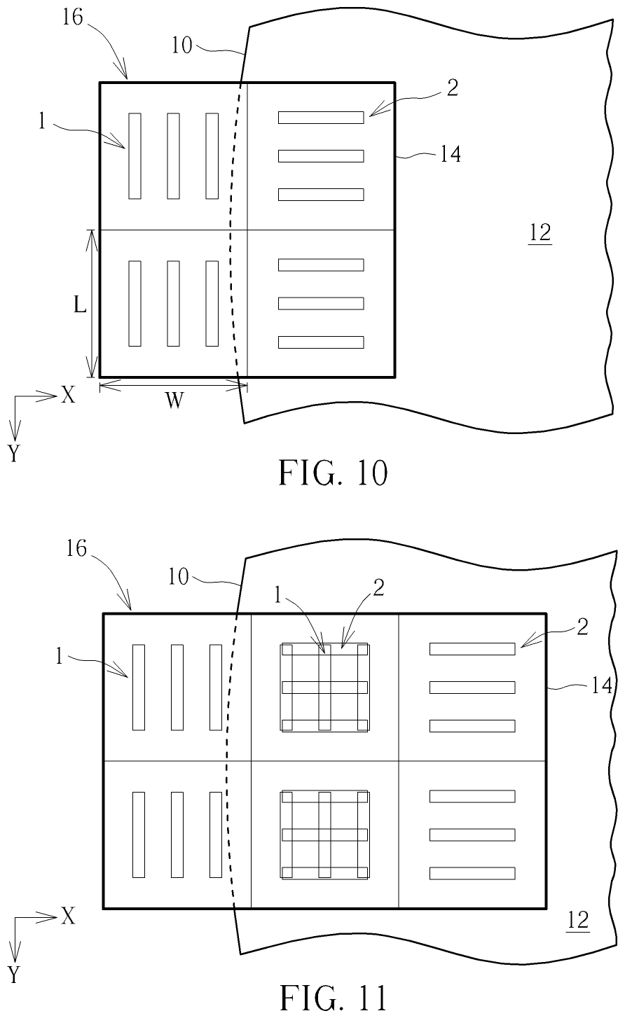

FIG. 1 and FIG. 3 depict a double exposure process according to a first preferred embodiment of the present invention. FIG. 2 shows a first pattern and a second pattern on a photoresist after Step (a). FIG. 4 shows a first pattern and a second pattern on a photoresist after Step (c).

As shown in FIG. 1, a wafer 10 is provided. The wafer 10 is covered by a photoresist 12. Then, a reticle 14 is provided. The reticle 14 includes n×m regions 16 that is arranged in n rows and m columns, wherein m is a positive integer starting from 1, 2 to A, A is not less than 2 and n is a positive integer starting from 1 to B, B is not less than 1. According to an example in FIG. 1, n is 6 (B is 6) and m is 12 (A is 12). However, the number of n and m can be altered based on different requirements. As long as m is not less than 2 and n is not less than 1.

Furthermore, each of the regions in the n×m regions 16 has the same length L and the same width W. In other words, all of the n×m regions 16 have the same size and the same shape. Each of the regions in the n×m regions 16 represents a range of a die. It is noteworthy that a first pattern 1 is disposed within an mth column of the n×m region 16 with an odd-numbered m, and a second pattern 2 is disposed within an mth column of the n×m region 16 with an even-numbered m and the first pattern 1 is different from the second pattern 2. In details, as shown in FIG. 1, a first pattern 1 is disposed in the 1st column, the 3rd column, the 5th column, the 7th column, the 9th column and the 11th column of the n×m regions 16. A second pattern 2 is disposed in the 2nd column, the 4th column, the 6th column, the 8th column, the 10th column, and the 12th column of the n×m regions 16.

According to a first preferred embodiment of the present invention, a double exposure process includes steps of Step (a), Step (b) and Step (c) illustrated as follows.

Step (a) includes performing a first exposure by illuminating a light through the n×m regions 16 on the reticle 14 to transfer at least the second pattern 2 onto the photoresist 12.

Step (b) includes moving the reticle 14 a distance of the width W along a first direction X which is parallel to the rows.

Step (c) includes performing a second exposure by illuminating the light through the n×m regions 16 on the reticle 14 to transfer the first pattern 1 and the second pattern 2 onto the photoresist 16. The steps are performed in a sequence of Step (a), Step (b) and Step (c).

Step (a), Step (b) and Step (c) are exemplified in detail from FIG. 1 to FIG. 2. As shown in FIG. 1, in Step (a), the reticle 14 is disposed on the wafer 10. Later, a first exposure is performed by illuminating a light through the 6×12 regions 16 on the reticle 14 to transfer the first pattern 1 and the second pattern 2 onto the photoresist 12. It is noteworthy that part first pattern 1 in the 1st column of the 6×12 regions 16 is projected outside of the wafer 10. The first pattern 1 and the second pattern 2 in the rest of the columns are projected inside of the wafer 10. As shown in FIG. 2, numerous first patterns 1 and numerous second patterns 2 are transferred on the photoresist 12 after Step (a). The range of the 6×12 regions 16 on the photoresist 12 is shown by dotted lines for clearly showing the columns and rows. In practice, only the first pattern 1 and the second pattern 2 are printed on the photoresist 12.

As shown in FIG. 3, in Step (b), the reticle 14 is moved in a distance of the width W along a first direction X which is parallel to the rows. The dotted lines E1 and E2 in FIG. 3 respectively mark the left edge and the right edge of the reticle 14 in Step (a). After that, in Step (c), a second exposure performed by illuminating the light through the 6×12 regions 16 on the reticle 14 to transfer the first pattern 1 and the second pattern 2 onto the photoresist 12. Because the reticle 14 in in Step (b) only moves one width W of one region, this makes the mth column with an odd-numbered on reticle 14 of Step (b) overlay the mth column with an even-numbered on reticle 14 of Step (a).

As shown in FIG. 4, after Step (c), the first pattern 1 is transferred onto the region of photoresist 12 with the second pattern 2 already therein, and the second pattern 2 is transferred onto the region of the photoresist 12 with the first pattern 1 already therein expect the 1st column and the last column on the photoresist 12. Now, the double exposure process is completed.

Because the first pattern 1 and the second pattern 2 are different but they use the same light to perform the exposure, a light polarizing material can be added to the reticle 14 or a phase shift reticle can be used as the reticle 14 to make the exposure rate of the first pattern 1 and the second pattern 2 the same.

Furthermore, after moving the reticle 14 with the width W, at least part of the second pattern 2 within the last column of the 6×12 regions 16 is projected outside of the wafer 10. In Step (a) to Step (c) the reticle 14 is moved along the first direction X, and the trail of the reticle 14 form a “big row”. The wafer 10 along the big row is entirely overlapped by the reticle 14 by only moving one of width W. Therefore, the double exposure process is stopped at Step (c).

On the other hand, if the wafer 10 along the big row can't be entirely overlapped by only moving the reticle 14 once, Step (d), Step (e) and a repeating step (b) and a repeating Step (c) need to be added to complete the double exposure process. The following illustration demonstrates a double exposure process including Step (a) to Step (e) according to a second preferred embodiment of the present invention.

FIG. 5 to FIG. 8 shows a double exposure process according to a second preferred embodiment of the present invention, wherein like reference numerals are used to refer to like elements throughout. More specifically speaking, FIG. 5 shows the process of Step (a) and FIG. 6 shows the process of Step (b) and Step (c). FIG. 7 shows Step (d) and Step (e). FIG. 8 shows a step (b) which is repeated and a Step (c) which is repeated. The difference between the first preferred embodiment and the second preferred embodiment is that the relative size between the reticle 14 and the wafer 10. The concept of Step (a), Step (b) and Step (c) in the second preferred embodiment is the same as that of the Step (a), Step (b) and Step (c) in the first preferred embodiment. The concept of the pattern layout on the reticle 14 is also the same in the first preferred embodiment and the second preferred embodiment. Therefore, the detail of Step (a), Step (b), Step (c) and the pattern layout is omitted here.

As shown in FIG. 5, a wafer 10 covered by a photoresist 12 is provided. A reticle 14 with n×m regions 16 thereon is provided. In this embodiment, n is 10 (B is 10) and m is 10 (A is 10). A first pattern 1 is disposed on the mth column with an odd-numbered m, and a second pattern 2 is disposed on the mth column with even-numbered m. In step (a), a first exposure is performed by illuminating a light through the 10×10 regions 16 on the reticle 14 to transfer the first pattern 1 and the second pattern 2 onto the photoresist 12. As shown in FIG. 6, the reticle 14 is moved a distance of the width W along a first direction X which is parallel to the rows. Later, a second exposure is performed by illuminating the light through the 10×10 regions 16 on the reticle 14 to transfer the first pattern 1 and the second pattern 2 onto the photoresist 12. After the second exposure, the first pattern 1 is transferred onto the region with the second pattern 2 already therein, and the second pattern 2 is transferred onto the region with the first pattern 1 already therein expect the 1st column and the last column on the photoresist 12. Please refer to FIG. 4 to see the result of the patterns on the photoresist 12, although the number of n and m is different between FIG. 4 and this embodiment but the concept is the same.

As shown in FIG. 7, in Step (d), the reticle 14 is moved a distance of A−1 times of the width W along the first direction X after Step (c). Because A is 10 in this embodiment, the reticle 14 is moved a distance of 9 times of the width W.

In step (e), a third exposure is performed by illuminating the light through the 10×10 regions 16 on the reticle 14 to transfer the first pattern 1 and the second pattern 2 onto the photoresist 12 after Step (d).

Moreover, because the 1st column of the reticle 14 in Step (d) overlays the last column of the reticle 14 in Step (b), the region on the photoresist 12 corresponding to the last column of the reticle 14 in Step (b) can be patterned by the first pattern 1 in Step (e). Furthermore, after Step (e), the region on the photoresist 12 corresponding to the 2nd column to the 10th column of the reticle 14 in Step (e) only has one kind of the pattern (either a first pattern 1 or a second pattern 2) in each column. Therefore, a repeating Step (b) and a repeating Step (c) need to be performed to add another different pattern on the corresponding region of the photoresist 12.

As shown in FIG. 8, a repeating Step (b) is performed by moving the reticle 14 a distance of the width W along a first direction X parallel to the rows. Then, a repeating Step (c) is performed by performing a fourth exposure by illuminating the light through the 10×10 regions 16 on the reticle 14 to transfer the first pattern 1 and the second pattern 2 onto the photoresist 12. It is noteworthy that after the repeating Step (c), part of the second pattern 2 in the last column of the reticle 14 is projected outside of the wafer 10, which means the wafer 10 along the big row is entirely exposed by the reticle 14. Therefore, the double exposure process can be stopped at the repeating Step (c). Now, a double exposure process of the second preferred embodiment is completed.

If after the step in FIG. 8, the wafer 10 along the big row is still not entirely exposed by the reticle 14, repeating Step (d), Step (e), Step (b) and (c) in sequence until the pattern in the last column of the n×m regions 16 is projected outside of the wafer 10.

FIG. 9 shows another exposure method according to a third preferred embodiment of the present invention. As shown in FIG. 9, after Step (a) and before Step (b), a Step (a1) is performed by moving the reticle 14 B times of the length L along a second direction Y parallel to the column followed by transferring patterns on the reticle 14 onto the photoresist 12. Step (a1) is repeated until the last row of the n×m regions 16 is projected outside of the wafer 10. During repeating Step (a1), the reticle 14 moves along the second direction Y and the trail of the reticle 14 form a “big column”. In this way, the wafer 10 along the big column is entirely exposed by the reticle 14.

The same concept can be applied to Step (c) and Step (e). For example, after Step (c) and before step (d), the reticle 14 is moved B times of the length L along the second direction Y parallel to the column followed by transferring patterns on the reticle 14 onto the photoresist 12. In this way, the region on the wafer 10 along the same big column can be all exposed.

FIG. 10 to FIG. 11 show an example of a first pattern and an example of a second pattern according to a fourth preferred embodiment of the present invention, wherein like reference numerals are used to refer to like elements throughout. As shown in FIG. 10, a wafer 10 covered by a photoresist 12 is provided. A reticle 14 with 2×2 regions 16 is provided. The first pattern 1 includes line patterns arranged separated from each other along a second direction Y, and the second pattern 2 includes line patterns arranged separated from each other along a first direction X which is perpendicular to the second direction Y. In FIG. 10, Step (a) is preformed to project the patterns on the reticle 14 onto the photoresist 12.

As shown in FIG. 11, Step (b) and Step (c) are performed by moving the reticle 14 a width W along a first direction X followed by projecting the patterns on the reticle 14 onto the photoresist 12. In order to demonstrate the overlapping columns of the 2×2 regions 16 in Step (a) and Step (c), the position of the reticle 14 in Step (a) is kept in FIG. 11. Please still refer to FIG. 11, the 1st column of the 2×2 regions 16 in the reticle 14 of Step (c) overlays the 2nd column of the 2×2 regions 16 in the reticle 14 of Step (a), therefore form a double exposure pattern.

A double exposure process generally utilized two reticles in a conventional method. A given layout is split or decomposed into two sets of patterns, and are printed using a separate mask in a separate exposure step. Therefore, in conventional double exposure method, reticles need to be changed and relative positions between the reticle and the wafer needs to be aligned again after changing the reticle. Therefore the overlay region of two decomposed patterns is prone to suffer offset problems because the reticle is aligned again.

The reticle of the present invention integrates two different patterns thereon. By using the reticle and a reticle moving method in the present invention, a double exposure process can be performed using only one reticle. This means, the reticle doesn't need to be changed, and the alignment offset between the reticle and the wafer can be prevented.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A double exposure process, comprising:
providing a reticle comprising n×m regions that is arranged inn rows and m columns, wherein m is a positive integer starting from 1, 2 to A, A is not less than 2 and n is a positive integer starting from 1 to B, B is not less than 1, each of the n×m regions has the same length and the same width, a first pattern is disposed within an mth column of the n×m regions with an odd-numbered m, and a second pattern is disposed within an mth column of the n×m region with an even-numbered m, and the first pattern is different from the second pattern;
providing a wafer covering by a photoresist;
performing a double exposure process comprising steps of:
Step (a): performing a first exposure by illuminating a light through the n×m regions on the reticle to transfer the second pattern onto the photoresist;
Step (b): moving the reticle a distance of the width along a first direction which is parallel to the rows; and
Step (c): performing a second exposure by illuminating the light through the n×m regions on the reticle to transfer the first pattern and the second pattern onto the photoresist; wherein the steps are performed in a sequence of Step (a), Step (b) to Step (c).

2. The double exposure process of claim 1, further comprising:
Step (d): moving the reticle a distance of A-1 times of the width along the first direction after Step (c);
Step (e): performing a third exposure by illuminating the light through the n×m regions on the reticle to transfer the first pattern and the second pattern onto the photoresist after Step (d).

3. The double exposure process of claim 2, further comprising after Step (e), repeating Step (b) and Step (c) in sequence to make the first pattern or the second pattern in the last column of the n×m regions projected outside of the wafer.

4. The double exposure process of claim 2, further comprising after Step (e), repeating Step (b), Step (c), Step (d), Step (e) Step (b), Step (c) in sequence, until the first pattern or the second pattern in the last column of the n×m regions is projected outside of the wafer.

5. The double exposure process of claim 1, wherein during Step (a), the first pattern in the first column of the n×m regions is projected outside of the wafer.

6. The double exposure process of claim 1, further comprising after Step (a) and before Step (b), moving the reticle a distance of the length along a second direction which is parallel to the columns.

7. The double exposure process of claim 1, wherein after Step (a) and before Step (b), a plurality of first patterns and a plurality of second patterns are respectively transferred onto a plurality of regions on the photoresist.

8. The double exposure process of claim 7, wherein after Step (c), a plurality of first patterns are transferred onto the plurality of regions on the photoresist with the second pattern therein, and a plurality of second patterns are transferred onto the plurality of regions on the photoresist with the first pattern therein.

9. The double exposure process of claim 1, wherein the first pattern comprising line patterns arranged separated from each other along a second direction, and the second pattern comprising line patterns arranged separated from each other along the first direction which is perpendicular to the second direction.

10. The double exposure process of claim 1, wherein the reticle includes a light polarizing material.

11. The double exposure process of claim 1, wherein the reticle is a phase shift reticle.
